(19) United States
(12) Patent Application Publication
(10) Pub. No.: US 2026/0219420 A1
(43) Pub. Date: Jul. 30, 2026

(54) SYSTEMS AND METHODS FOR OPTIMIZING TERRAIN GRADING ON TRIANGULATED IRREGULAR NETWORK SURFACES

(71) Applicant: SITE SUITE, INC, Petaluma, CA (US)

(72) Inventors: Christian Lucas Kjeldsen, Petaluma, CA (US); Jordan Cannon, Kenosha, WI (US)

(21) Appl. No.: 19/578,758

(22) Filed: Mar. 25, 2026

Related U.S. Application Data
(63) Continuation-in-part of application No. 19/245,312, filed on Jun. 21, 2025.
(60) Provisional application No. 63/663,457, filed on Jun. 24, 2024.

(51) Int. Cl. G01V 20/00; G06F 30/23; G06T 17/20; G06T 19/20

(52) U.S. Cl. CPC G01V 20/00; G06F 30/23; G06T 17/20; G06T 19/20; G06T 2219/2021

(57) ABSTRACT

The present disclosure relates to methods and systems for grading design. The method performed by a system includes receiving three-dimensional (3D) surface data including a plurality of spatial data points representing a terrain elevation. The method includes generating an adjacency structure including connections between neighboring spatial data points. Further, the method includes generating an elevation adjustment variable representing a modification to the terrain elevation. The method includes generating constraint data defining a permissible elevation difference for each pair of the neighboring spatial data points identified in the adjacency structure. The method includes generating optimization input data comprising the elevation adjustment variable for each spatial data point and the constraint data. Furthermore, the method includes processing the optimization input data to determine adjusted elevation values for the plurality of spatial data points satisfying the constraint data. The method includes generating modified 3D surface data representing a graded terrain surface.

### TECHNICAL FIELD

The present disclosure relates to grading design, and more particularly to systems and methods for generating topography grades.

### BACKGROUND

At a construction site, grading is performed to reshape the land surface to achieve desired elevations and slopes. Grading operations may include raising or lowering ground levels, modifying slope directions, and shaping terrain to support drainage, structural foundations, roadways, rail systems, utility installations, solar arrays, agricultural development, and other infrastructure. Proper grading ensures that stormwater flows appropriately, structural loads are supported as intended, and long-term site stability is maintained. Grading criteria typically depend on site conditions, engineering requirements, regulatory constraints, and project-specific design objectives. Slopes must be configured to control erosion, manage runoff, ensure accessibility, and provide compatibility with surrounding terrain and constructed elements. In practice, grading design frequently requires balancing multiple factors, including slope limitations, smoothness considerations, drainage behavior, and earthwork quantities.

Modern surveying technologies generate three-dimensional (3D) representations of existing terrain surfaces using methods such as total-station measurement, satellite-based positioning systems, LiDAR scanning, and photogrammetry. These technologies produce digital surface models that are subsequently processed using computer-aided design (CAD) or other terrain modeling software to develop proposed grading plans. Existing computer-implemented grading techniques often involve iterative manual adjustment of elevations, contour editing, or trial-and-error refinement within software environments. In many cases, users must repeatedly adjust slope parameters, regenerate surface representations, and review earthwork calculations to achieve acceptable results. Such processes may be time-consuming, computationally intensive, and dependent on user expertise. Further, conventional approaches may require repeated recalculation and adjustment to reconcile local slope conditions with global grading requirements.

Therefore, there exists an improved, less time-consuming, cost-effective, and simpler computer-implemented grading design method and server systems for generating the grading design of a topography (i.e., the construction sites).

### SUMMARY

In an embodiment, a computer-implemented method is disclosed. The computer-implemented method performed by a system includes receiving three-dimensional (3D) surface data including a plurality of spatial data points representing a terrain elevation. The method includes generating an adjacency structure including connections between neighboring spatial data points. The adjacency structure corresponds to an irregular mesh representation including edges having variable spatial lengths determined from coordinates of the neighboring spatial data points. Further, the method includes generating an elevation adjustment variable representing a modification to the terrain elevation at a corresponding spatial data point of the plurality of spatial data points. The method includes generating constraint data defining a permissible elevation difference for each pair of the neighboring spatial data points identified in the adjacency structure. The permissible elevation difference is determined based on a slope tolerance, and a spatial distance between each of the neighboring spatial data points. The method includes generating optimization input data comprising the elevation adjustment variable for each spatial data point and the constraint data. Furthermore, the method includes processing the optimization input data to determine adjusted elevation values for the plurality of spatial data points satisfying the constraint data. The method includes generating modified 3D surface data based on the adjusted elevation values. The modified 3D surface data represent a graded terrain surface.

In another embodiment, a system is disclosed. The system includes a communication interface, a memory configured to store instructions, and a processor communicably coupled to the communication interface and the memory. The processor is configured to execute the instructions stored in the memory and thereby cause the system to receive three-dimensional (3D) surface data including a plurality of spatial data points representing a terrain elevation. The system is caused to generate an adjacency structure comprising connections between neighboring spatial data points. The adjacency structure corresponds to an irregular mesh representation including edges having variable spatial lengths determined from coordinates of the neighboring spatial data points. Further, the system is caused to generate an elevation adjustment variable representing a modification to the terrain elevation at a corresponding spatial data point of the plurality of spatial data points. The system is caused to generate constraint data defining a permissible elevation difference for each pair of the neighboring spatial data points identified in the adjacency structure. The permissible elevation difference is determined based on a slope tolerance, and a spatial distance between each of the neighboring spatial data points. The system is caused to generate optimization input data comprising the elevation adjustment variable for each spatial data point and the constraint data. Furthermore, the system is caused to process the optimization input data to determine adjusted elevation values for the plurality of spatial data points satisfying the constraint data. The system is caused to generate modified 3D surface data based on the adjusted elevation values. The modified 3D surface data represent a graded terrain surface.

### BRIEF DESCRIPTION OF THE DRAWINGS

The following detailed description of illustrative embodiments is better understood when read in conjunction with the appended drawings. For the purpose of illustrating the present disclosure, exemplary constructions of the disclosure are shown in the drawings. However, the present disclosure is not limited to a specific device or a tool and instrumentalities disclosed herein. Moreover, those in the art will understand that the drawings are not to scale. Wherever possible, like elements have been indicated by identical numbers:

FIG. 1 illustrates an example representation of an environment related to at least some example embodiments of the present disclosure;

FIG. 2 is a block diagram of a server system configured to perform grading design, in accordance with an embodiment of the disclosure;

FIG. 3 illustrates an example representation of a three-dimensional (3D) terrain surface and a corresponding triangulated irregular network (TIN) generated from a plurality of spatial data points, in accordance with an embodiment of the present disclosure;

FIGS. 4A and 4B illustrate an example representation of an isotropic slope constraint applied between neighboring spatial data points within an adjacency structure defined by the triangulated irregular network (TIN), in accordance with an embodiment of the present disclosure;

FIG. 5A illustrates an example representation of a curvature or slope-change constraint generated using a near-colinear triplet of spatial data points within an adjacency structure defined by the triangulated irregular network (TIN), in accordance with an embodiment of the present disclosure;

FIG. 5B illustrates an example representation of an interior face slope constraint applied within a triangular face of the triangulated irregular network, in accordance with an embodiment of the present disclosure;

FIG. 6 illustrates a flow diagram representing a two-phase optimization workflow for generating a graded terrain surface, in accordance with an embodiment of the present disclosure; and

FIG. 7 illustrates a flowchart of a computer-implemented method for grading designs of the TIN, in accordance with an embodiment of the present disclosure.

The drawings referred to in this description are not to be understood as being drawn to scale except if specifically noted, and such drawings are only exemplary in nature.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification does not necessarily refer to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

### Overview

The present disclosure relates to computer-implemented techniques for generating grading designs for construction sites based on three-dimensional (3D) terrain data. In particular, the disclosure provides systems and methods for adjusting terrain elevations represented as irregularly spaced spatial data points organized in an irregular mesh, such as a triangulated irregular network (TIN), while satisfying slope-related and earthwork-related constraints.

The method performed by a system includes receiving 3D surface data including a plurality of spatial data points representing terrain elevations. An adjacency structure is generated including connections between neighboring spatial data points, wherein the adjacency structure corresponds to an irregular mesh representation including edges having variable spatial lengths determined from coordinates of the neighboring spatial data points. For each spatial data point, an elevation adjustment variable is generated representing a modification to the terrain elevation at that spatial data point.

Further, constraint data is generated defining a permissible elevation difference for each pair of neighboring spatial data points identified in the adjacency structure. The permissible elevation difference is determined based on at least a slope tolerance and a spatial distance between the neighboring spatial data points. In certain embodiments, directional slope constraints are generated based on directional components of each edge, enabling different slope tolerances to be applied depending on edge orientation relative to predefined directional axes. Furthermore, optimization input data including the elevation adjustment variables and the generated constraint data is processed to determine adjusted elevation values satisfying the constraint data. Additionally, modified 3D surface data representing a graded terrain surface is generated based on the adjusted elevation values.

In some embodiments, adjacency relationships are determined by generating a triangulated irregular network (TIN) from irregularly spaced survey data points. The irregular mesh representation enables slope constraints to be enforced along variable-length edges directly derived from spatial coordinates. Also, additional constraints are generated to regulate slope-change between neighboring edges sharing a common spatial data point, thereby limiting abrupt changes in grade. Interior face slope constraints may also be generated within triangular regions of the irregular mesh to ensure slope compliance across entire surface faces.

In some embodiments, earthwork volume is determined based on areas of triangular regions defined by the adjacency structure and elevation changes at vertices associated with each triangular region. A predefined earthwork volume condition may be enforced by constraining a difference between total positive elevation adjustments and total negative elevation adjustments to satisfy a predetermined net cut or fill requirement. In one embodiment, a two-phase processing workflow is performed. In a first phase, baseline adjusted elevation values are determined to minimize total elevation displacement while satisfying slope constraints. In a second phase, a net-volume requirement is enforced while limiting deviation from slope relationships established during the first phase. In certain implementations, drainage direction established during the first phase is preserved during the second phase by preventing reversal of slope direction between selected neighboring spatial data points. The processing may be performed using one or more adjustment procedures, including linear adjustment procedures, quadratic adjustment procedures that reduce localized elevation variation, or discrete-constrained adjustment procedures configured to preserve selected slope directions.

The disclosed systems and methods enable efficient generation of grading designs directly on irregular mesh representations of terrain, supporting flexible slope control, directional grading requirements, and accurate earthwork evaluation while reducing manual iteration.

The present disclosure provides several technical advantages in the field of computer-implemented terrain grading and surface optimization. One such advantage is grading operations are performed directly on an irregular mesh representation of terrain, such as a triangulated irregular network (TIN), rather than requiring transformation into a uniform grid. By utilizing adjacency relationships defined by variable-length edges derived from spatial coordinates, slope constraints may be enforced consistently across irregularly spaced survey data points. This enables adaptive surface representation in which node density corresponds to terrain complexity.

Additionally, directional (axis-component) slope constraints may be applied based on directional components of each edge. By allowing different slope tolerances to be applied depending on edge orientation relative to predefined directional axes, the system supports engineering requirements such as controlled drainage flow, roadway alignment, or directional surface grading. This directional flexibility enhances grading precision without requiring manual adjustment of individual surface regions. Also, higher-order constraints are generated to limit changes in slope between adjacent edges and to enforce slope compliance across interior regions of triangular faces. These constraints reduce abrupt grade transitions and improve smoothness of the resulting terrain surface while maintaining compliance with specified slope tolerances.

Furthermore, earthwork volume is computed using triangular regions defined by the irregular mesh. Volume contributions are determined based on areas of triangular faces and elevation changes at associated vertices. This triangle-based computation improves volume evaluation consistency for irregular surface representations and supports accurate net cut and fill targeting. The present disclosure implements a multi-stage processing workflow, where a first stage determines baseline adjusted elevations that minimize overall elevation displacement while satisfying slope constraints, and a second stage enforces a predefined net-volume requirement while limiting deviation from slope relationships established in the first stage. This staged approach enables volume targeting while preserving previously established slope continuity and, in certain embodiments, drainage direction. The result is improved surface stability and reduced likelihood of unintended grade reversals.

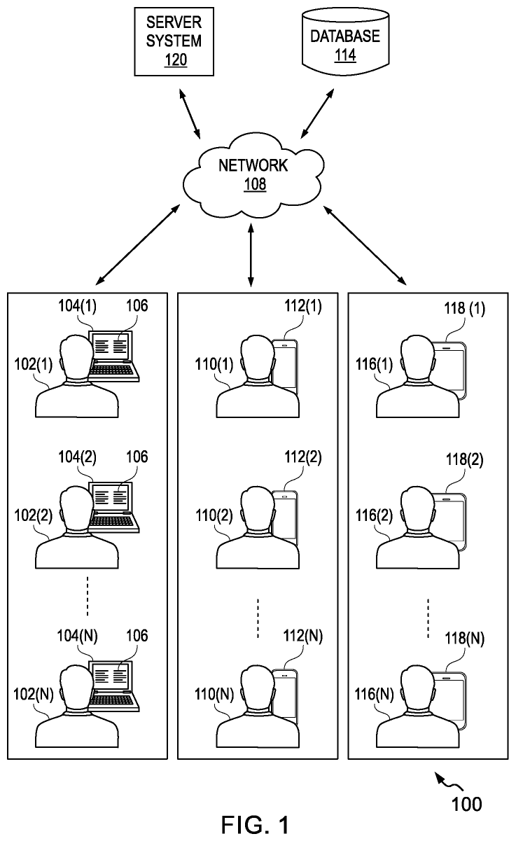

Various embodiments of the present disclosure are described hereinafter with reference to FIG. 1 to FIG. 7.

FIG. 1 illustrates an example representation of an environment 100 related to at least some example embodiments of the present disclosure. The environment 100 depicts a plurality of users (see, 102(1), 102(2), . . . , 102(N)), wherein ‘N’ is a natural number. Each of the plurality of users 102(1)-102(N) is associated with a respective electronic device (see, 104(1), 104(2), . . . , 104(N)). A user (e.g., the user 102(1)) may be a designer, engineer, or other technical expert who provides inputs for generating a grading design based on three-dimensional (3D) surface data. The user 102(1) may access a website 106 using an electronic device 104(1), such as a desktop computer, to obtain existing 3D surface data, upload updated surface representations, input grading parameters, specify slope-related conditions, define project requirements, and review generated grading outputs. The website 106 is depicted for illustration purposes and may correspond to a platform provided by a construction entity or engineering service provider. In some embodiments, the website 106 may be replaced with a standalone mobile or desktop application. The plurality of users 102(1)-102(N) may access the system using various electronic devices including smartphones, tablets, laptop computers, personal digital assistants, or other web-enabled computing devices.

The environment 100 further depicts a plurality of site experts (see, 110(1), 110(2), . . . , 110(N)), each associated with a respective electronic device (see, 112(1), 112(2), . . . , 112(N)). The site experts 110(1)-110(N) may include surveyors, field engineers, or equipment operators. In one embodiment, the site experts perform surveys of a construction site to obtain terrain elevation data representing existing ground conditions. The 3D surface data obtained from surveying operations may include spatial data points representing irregularly spaced terrain measurements. The collected surface data may be transmitted to a database 114 via a communication network 108. The site expert 110(1) may access the website 106 using the electronic device 112(1) to upload survey data, review terrain models, or verify site information. The electronic devices 112(1)-112(N) may include any suitable computing device capable of communication over the network 108.

The environment 100 further depicts a plurality of customers (see, 116(1), 116(2), . . . , 116(N)), each associated with a respective electronic device (see, 118(1), 118(2), . . . , 118(N)). The customers 116(1)-116(N) may be property owners, developers, project managers, or other stakeholders responsible for defining grading objectives for the construction site. The customer 116(1) may access the web application or mobile application using the electronic device 118(1) to provide requirement data, such as site boundaries, installation locations, earthwork targets, drainage considerations, or other project-specific constraints. The requirement data may be stored in the database 114 via the communication network 108. The plurality of customers 116(1)-116(N) may access the system using various electronic devices including smartphones, tablets, laptops, or other network-enabled devices.

The plurality of electronic devices 104(1)-104(N), 112(1)-112(N), and 118(1)-118(N) may include applications such as web browser applications or dedicated client software to access the website 106. The website 106 may be hosted on a remote server and configured to retrieve or transmit data via the communication network 108. In alternate embodiments, the website 106 may be replaced with a standalone application that communicates directly with a remote application server through an application programming interface (API). The communication network 108 may include wired networks, wireless networks, or a combination thereof, including local area networks (LANs), wide area networks (WANs), cellular networks, or the Internet.

The environment 100 further depicts a server system 120 (hereinafter referred to as “the system”) configured to generate a grading design for a construction site based on 3D surface data and associated constraint information. In some embodiments, the database 114 may be integrated with the system 120 and may store existing 3D surface data, constraint data, requirement data, and configuration parameters. The system 120 may receive existing surface data from site experts, constraint parameters from users (e.g., designers), and requirement data from customers. The system 120 may access such data from the database 114 or directly from one or more electronic devices via the communication network 108.

The existing 3D surface data represents terrain elevation information for the construction site. The surface data may comprise a plurality of spatial data points representing irregularly spaced measurements of ground elevation. The constraint data represents grading-related conditions to be satisfied during generation of the modified surface, including permissible slope conditions between neighboring spatial data points and allowable variations in slope across adjacent regions. In certain embodiments, the constraint data may include directional slope parameters corresponding to different spatial orientations. Based on requirement data provided by customers, a user (e.g., the user 102(1)) may configure constraint data suitable for the intended construction purpose.

The system 120 may generate adjacency relationships among the plurality of spatial data points of the existing 3D surface data, wherein neighboring spatial data points are identified based on spatial relationships. In some embodiments, the adjacency relationships may correspond to connections defined within an irregular mesh representation of the surface. The system 120 may associate an elevation adjustment variable with each spatial data point and determine adjusted elevation values that comply with the constraint data. Spatial data points located outside a specified grading region defined by the requirement data may be excluded from processing. The adjusted elevation values are applied to generate modified 3D surface data representing a graded terrain surface. The modified 3D surface data may be used for construction planning, visualization, or automated earthmoving operations.

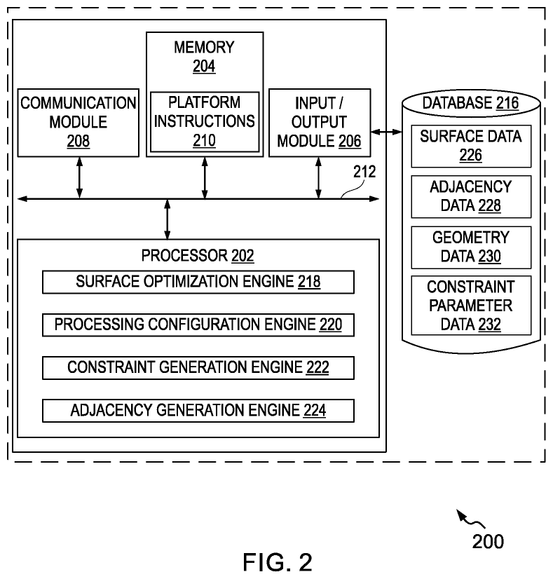

FIG. 2 is a block diagram of a system 200 configured to generate a grading design for the TIN, in accordance with an embodiment of the disclosure. The system 200 is depicted to include a processor 202, a memory 204, an input/output (I/O) module 206, and a communication module 208. It is noted that although the system 200 is depicted to include the processor 202, the memory 204, the input/output (I/O) module 206, and the communication module 208, in some embodiments, the system 200 may include more or fewer components than those depicted herein. The various components of the system 200 may be implemented using hardware, software, firmware, or any combination thereof. The system 200 depicted in FIG. 2 is similar to the system 120 depicted in FIG. 1.

In one embodiment, the processor 202 may be embodied as a multi-core processor, a single-core processor, or a combination of one or more multi-core processors and one or more single-core processors. For example, the processor 202 may be embodied as one or more of various processing devices, such as a coprocessor, a microprocessor, a controller, a Digital Signal Processor (DSP), a processing circuitry with or without an accompanying DSP, a Graphics Processing Unit (GPU), a System on a Chip (Soc), or various other processing devices including integrated circuits such as, for example, an Application Specific Integrated Circuit (ASIC), a field programmable gate array (FPGA), a microcontroller unit (MCU), a hardware accelerator, a special-purpose computer chip, or the like.

In one embodiment, the memory 204 is capable of storing machine-executable instructions, referred to herein as platform instructions 210. Further, the processor 202 is capable of executing the platform instructions 210. In an embodiment, the processor 202 may be configured to execute hard-coded functionality. In an embodiment, the processor 202 is embodied as an executor of software instructions, wherein the instructions may specifically configure the processor 202 to perform the algorithms and/or operations described herein when the instructions are executed. For example, in at least some embodiments, each component of the processor 202 may be configured to execute instructions stored in the memory 204 for realizing respective functionalities, as will be explained in further detail later.

In an embodiment, the I/O module 206 may include mechanisms configured to receive inputs from and provide outputs to an operator of the system 200. The term ‘operator of the system 200’ as used herein may refer to at least the user 102(1), the site expert 110(1), and the customer 118(1). To enable the reception of inputs and provide outputs to the system 200, the I/O module 206 may include at least one input interface and/or at least one output interface. Examples of the input interface may include, but are not limited to, a keyboard, a mouse, a joystick, a keypad, a touch screen, soft keys, a microphone, and the like. Examples of the output interface may include but are not limited to, a display such as a light-emitting diode display, a thin-film transistor (TFT) display, a liquid crystal display, an Active-Matrix Organic Light-Emitting Diode (AMOLED) display, a microphone, a speaker, a ringer, and the like. In an example embodiment, at least one module of the system 200 may include an I/O circuitry (not shown in FIG. 2) configured to control at least some functions of one or more elements of the I/O module 206, such as, for example, a speaker, a microphone, a display, and/or the like. The processor 202 of the system 200 and/or the I/O circuitry may be configured to control one or more functions of the elements of the I/O module 206 through computer program instructions, for example, software and/or firmware, stored on a memory, for example, the memory 204, and/or the like, accessible to the processor 202 of the system 200.

In some embodiments, the processor 202 and/or other components of the processor 202 may access the storage module 204 using a storage interface (not shown in FIG. 2). The storage interface may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing the processor 202 and/or other components of the processor 202 with access to the storage module 204.

The processor 202 may include a surface optimization engine 218, a processing configuration engine 220, a constraint generation engine 222, and an adjacency generation engine 224. Each engine within the processor 202 may be implemented in hardware, software, firmware, or any combination thereof.

The processing configuration engine 220 is configured to at least a) allow the user 102(1) to pre-set at least one processing mode and corresponding processing parameters using the electronic device 104(1); b) allow the user 102(1) to modify the processing parameters; c) send available processing options to the electronic device 104(1) based on requirement data received from the customer 116(1); d) receive a selected processing configuration from the user 102(1) at the time of grading; and e) send processing configuration information to the surface optimization engine 218 and the constraint generation engine 222. For example, the user 102(1) (e.g., designer) may input via a graphical user interface (GUI) at least one processing configuration specifying slope tolerances, directional slope limits, net volume targets, staged processing preferences, and the like. Depending on project requirements, additional configurations may be added to the processing configuration engine 220. After selecting a configuration, the selected parameters are applied to the received 3D surface data.

The adjacency generation engine 224 is configured to at least a) receive three-dimensional (3D) surface data comprising a plurality of spatial data points representing terrain elevations; b) generate an adjacency structure comprising connections between neighboring spatial data points; c) determine spatial distances between neighboring spatial data points based on their coordinates; and d) store adjacency data and geometry data in a database 216. In one embodiment, generating the adjacency structure comprises generating a triangulated irregular network (TIN) from irregularly spaced terrain measurements, wherein edges of the TIN define neighboring spatial data points. For each pair of neighboring spatial data points (i, j), a spatial distance d_ij is computed as:

$$d\_ij = sqrt ( ( x\_j - x\_i ) \hat{} 2 + ( y\_j - y\_i ) \hat{} 2 )$$

where (x_i, y_i) and (x_j, y_j) represent horizontal coordinates of the respective spatial data points. The adjacency structure, therefore, corresponds to an irregular mesh representation including edges having variable spatial lengths determined from the coordinates of the neighboring spatial data points.

The constraint generation engine 222 is configured to at least a) allow the user 102(1) to pre-set at least one constraint and corresponding parameter values; b) send available constraints to the user 102(1) at the time of grading; c) receive selected constraint data from the user; and d) generate constraint data defining permissible elevation differences for neighboring spatial data points. For each spatial data point i, an elevation adjustment variable is generated representing a modification to the terrain elevation, such that an adjusted elevation is expressed as:

$${z}^{′} \_i = z\_base \_i + u\_i - d\_i$$

where u_i represents a positive elevation adjustment and d_i represents a negative elevation adjustment.

For each pair of neighboring spatial data points (i, j), a permissible elevation difference is determined based on a slope tolerance S_max and the spatial distance d_ij, such that:

$$\vert {z}^{′} \_j - {z}^{′} \_i \vert \leq S\_max \times d\_ij$$

In one embodiment, directional slope constraints are generated based on directional components of each edge. For example:

$$\begin{matrix}dx = x\_j - x\_i \\ dy = y\_j - y\_i , and \\ \vert {z}^{′} \_j - {z}^{′} \_i \vert \leq S\_E \times dx\_pos + S\_W \times dx\_neg + S\_N \times dy\_pos + S\_S \times dy\_neg\end{matrix}$$

where S_E, S_W, S_N, and S_S represent directional slope tolerances corresponding to predefined axes.

The constraint generation engine 222 may further generate slope-change constraints limiting a rate of change of slope between neighboring spatial data points sharing a common spatial data point. For a triplet (j, i, k), a slope-change constraint may be expressed as:

$$\vert {z}^{′} \_j - {z}^{′} \_j ) / d\_ji - ( {z}^{′} \_i - {z}^{′} \_k ) / d\_ik \vert \leq Δ S\_max$$

Additionally, the constraint generation engine 222 may generate a predefined earthwork volume condition constraining a difference between a set of total positive elevation adjustments and a set of total negative elevation adjustments, such that:

$$\sum \_i α\_i ( u\_i + d\_i ) = V\_target$$

Where,
V_target specifies a predetermined non-zero net cut or fill requirement. In particular,
V_target represents the predefined net earthwork volume requirement, corresponding to a specified difference between total fill and total cut volumes for a grading region, such that V_target=0 represents a balanced grading condition, V_target>0 represents a net fill condition, and V_target<0 represents a net cut condition.
α_i represents a nodal area weight associated with spatial data point i, the nodal area weight being determined from areas of triangular regions of the triangulated irregular network that include the spatial data point, such that each triangular region contributes a proportional share of its plan-view area to its associated vertices.

The processing configuration engine 220 is further configured to access requirement data defining a target grading region and eliminate one or more spatial data points outside the target grading region from further processing. In certain embodiments, the processing configuration engine 220 controls a multi-stage grading process. In a first processing stage, baseline adjusted elevation values are determined satisfying slope constraints. In a second processing stage, a net-volume requirement is enforced while limiting deviation from slope relationships established during the first processing stage. In one embodiment, the drainage direction established during the first processing stage is maintained by preventing reversal of slope direction between selected neighboring spatial data points.

The surface optimization engine 218 is configured to at least a) receive the elevation adjustment variables and generated constraint data; b) process optimization input data comprising the elevation adjustment variables and constraint data; c) determine adjusted elevation values for the plurality of spatial data points satisfying the constraint data; and d) generate modified 3D surface data based on the adjusted elevation values. In one embodiment, processing determines adjusted elevation values that minimize an area-weighted total elevation displacement while satisfying the constraint data. For example, total elevation displacement may be represented as:

$$\sum \_i α\_i ( u\_i + d\_i ) = V\_target$$

### Wherein,

α_i represents a nodal area weight associated with spatial data point i, the nodal area weight being determined from areas of triangular regions of the triangulated irregular network that include the spatial data point, such that each triangular region contributes a proportional share of its plan-view area to its associated vertices. The nodal area weights thereby approximate surface area attribution for purposes of earthwork volume consistency across irregular mesh representations.

In other embodiments, alternative adjustment procedures may be used, including a linear adjustment procedure, a quadratic adjustment procedure minimizing:

$$\sum \_i α\_i ( u\_i \hat{} 2 + d\_i \hat{} 2 )$$

where the nodal area weights α_i correspond to associated triangular surface areas, or a discrete-constrained adjustment procedure configured to preserve selected slope directions or other geometric relationships while satisfying the constraint data.

The modified 3D surface data generated by the surface optimization engine 218 represents a graded terrain surface and may be configured to generate grading control data for automated earthmoving equipment.

The memory 204 is any computer-operated hardware suitable for storing and/or retrieving data. In one embodiment, the memory 204 is configured to store user data, customer data, site expert data, surface data, adjacency data, geometry data, constraint parameter data, requirement data, configuration data, and modified 3D surface data. The memory 204 may include multiple storage units, such as hard drives and/or solid-state drives. In some embodiments, the memory 204 may include distributed storage systems.

The database 216 may store surface data 226, adjacency data 228, geometry Data 230, and constraint parameter data 232. The surface data 226 may include irregularly spaced survey data points obtained from one or more sensing measurements (not shown). The adjacency data 228 may define neighboring spatial data points forming an irregular mesh. The geometry data 230 may include spatial distances and directional components associated with adjacency relationships. The constraint parameter data 232 may include slope tolerances, directional slope limits, slope-change limits, volume targets, and region definitions.

The communication module 208 may include communication circuitry configured to facilitate communication between the system 200 and remote electronic devices over a communication network. The communication module 208 may be configured to receive existing 3D surface data from site experts, receive requirement data from customers, receive configuration data from users, and transmit modified 3D surface data and grading control data.

The components of the system 200, including the processor 202, the memory 204, the input/output module 206, the communication module 208, and the database 216, may communicate via a centralized circuit system 212. The centralized circuit system 212 may include one or more printed circuit boards or communication interconnect structures enabling coordinated operation of the system components.

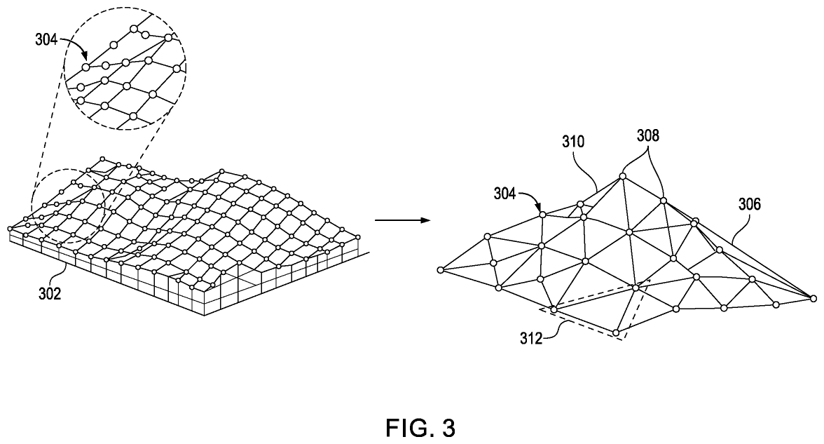

FIG. 3 illustrates an example representation of a three-dimensional (3D) terrain surface 302 and a corresponding triangulated irregular network (TIN) 306 generated from a plurality of spatial data points 304, in accordance with an embodiment of the present disclosure. The terrain surface 302 may represent existing ground elevations of a construction site obtained from survey measurements, remote sensing data, or other terrain acquisition techniques.

The spatial data points 304 may include irregularly spaced coordinate points, each associated with a horizontal position and a terrain elevation value. In one embodiment, each spatial data point may be represented by coordinates (x_i, y_i, z_i), where x_i and y_i represent horizontal coordinates and z_i represents an elevation value.

The triangulated irregular network (TIN) 306 is generated from the spatial data points 304 to define adjacency relationships between neighboring spatial data points. The TIN 306 includes a plurality of nodes 308 corresponding to the spatial data points 304, a plurality of edges 310 connecting neighboring nodes, and a plurality of triangular faces 312 defined by sets of three connected nodes.

As illustrated, the edges 310 have variable spatial lengths determined from the coordinates of the connected nodes. For any pair of neighboring nodes (i, j), an edge length may be determined based on the horizontal coordinate differences between the nodes. The variable edge lengths enable the irregular mesh representation to adapt to terrain complexity, allowing higher node density in regions of greater surface variation and lower density in relatively uniform regions.

Each triangular face 312 represents a planar region bounded by three edges of the edges 310. The triangular faces collectively approximate the continuous terrain surface 302. The adjacency relationships defined by the edges 310 are used by the system to generate constraint data for grading operations, including permissible elevation differences between neighboring nodes and additional constraints applied across triangular faces.

In certain embodiments, the TIN 306 may be generated using triangulation techniques that preserve breaklines or other site-specific features. However, the present disclosure is not limited to any specific triangulation algorithm. The adjacency structure defined by the TIN 306 forms the basis for subsequent constraint generation and elevation adjustment processing to generate a modified 3D surface representing a graded terrain surface.

The representation shown in FIG. 3 is illustrative and not limiting. Other irregular mesh configurations defining neighboring spatial data points and triangular regions may be employed without departing from the scope of the present disclosure.

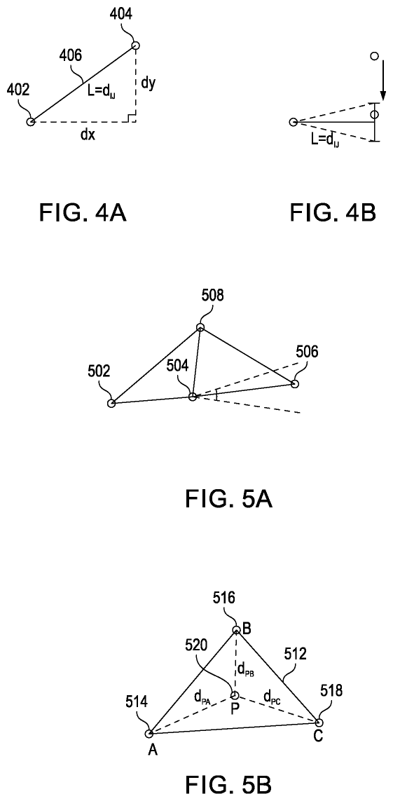

FIGS. 4A and 4B illustrate an example representation of an isotropic slope constraint applied between neighboring spatial data points within an adjacency structure defined by a triangulated irregular network (TIN), in accordance with an embodiment of the present disclosure.

As shown, a first node 402 and a second node 404 are connected by an edge 406. The edge 406 has a horizontal spatial distance denoted as L (or d_ij). The horizontal distance L is decomposed into orthogonal directional components, including a projection dx along a first horizontal axis and a projection dy along a second horizontal axis perpendicular to the first axis. The components dx and dy form a right-triangle relationship with L such that L corresponds to the resultant horizontal distance between the spatial data points.

Each node corresponds to a spatial data point having coordinates (x_i, y_i, z_i). The horizontal coordinate differences between the nodes define geometric parameters including:

$$\begin{matrix}dx = x\_j - x\_i \\ dy = y\_j - y\_i\end{matrix}$$

An edge length L (d_ij) is determined based on the horizontal distance between the nodes:

$$d\_ij = sqrt ( ( x\_j - x\_i ) \hat{} 2 + ( y\_j - y\_i ) \hat{} 2 )$$

In the illustrated embodiment, the slope constraint is isotropic, meaning that the permissible elevation difference between the nodes depends solely on the magnitude of the spatial distance between the nodes and not on directional orientation. Further, an adjusted elevation at each node may be represented as:

$${z}^{′} \_i = z\_base \_i + u\_i - d\_i$$

where u_i represents a positive elevation adjustment and d_i represents a negative elevation adjustment.

Each spatial data point is associated with an elevation value. A vertical elevation difference between spatial data points 402 and 404 is represented as Δz=z′_j−z′_i. In an isotropic slope constraint embodiment, the permissible elevation difference satisfies |Δz|≤S_max·L, where S_max represents a slope tolerance parameter, and L represents the horizontal distance between the spatial data points.

The permissible elevation difference between the nodes 402 and 404 is constrained such that:

$$\vert {z}^{′} \_j - {z}^{′} \_i \vert \leq S\_max \times d\_ij$$

where S_max represents a user-selected slope tolerance. The dashed boundary illustrated in FIG. 4 represents the maximum allowable elevation envelope defined by the slope tolerance S_max relative to the spatial distance d_ij. Thus, the isotropic slope constraint enforces a uniform slope limitation along the edge 406 regardless of the edge orientation within the horizontal plane.

In contrast to the isotropic constraint of FIG. 4, the directional slope constraint determines a permissible elevation difference based on directional components of the edge relative to predefined axes. For the edge 406 connecting nodes 402 and 404, horizontal directional components are determined as:

$$\begin{matrix}dx = x\_j - x\_i \\ dy = y\_j - y\_i\end{matrix}$$

Positive and negative directional components may be evaluated as:

$$\begin{matrix}dx\_pos = max ( dx , 0 ) \\ dx\_neg = max ( - dx , 0 ) \\ dy\_pos = max ( dy , 0 ) \\ dy\_neg = max ( - dy , 0 )\end{matrix}$$

Directional slope tolerances may be defined for multiple orientations, such as:

$$\begin{matrix}S\_E ( east ) \\ S\_W ( west ) \\ S\_N ( north ) , and \\ S\_S ( south ) .\end{matrix}$$

The permissible elevation difference between nodes 402 and 404 may therefore be defined as:

$$\vert {z}^{′} \_j - {z}^{′} \_i \vert \leq S\_E \times dx\_pos + S\_W \times dx\_neg + S\_N \times dy\_pos + S\_S \times dy\_neg$$

The allowable elevation envelope may differ depending on the orientation of the edge relative to the directional axes. This enables different slope tolerances to be applied depending on edge orientation, thereby accommodating site-specific engineering requirements such as drainage control, roadway grading, solar panel installation, or other directional grading objectives. In some embodiments, both isotropic and directional slope constraints may be generated for a given edge, and the more restrictive constraint may govern permissible elevation adjustment. Further, the embodiments illustrated in FIG. 4 are exemplary and not limiting. Edge-based constraint generation may be applied to all neighboring spatial data points defined within the adjacency structure of the triangulated irregular network.

FIG. 5A illustrates an example representation of a curvature or slope-change constraint generated using a near-colinear triplet of spatial data points within an adjacency structure defined by the triangulated irregular network (TIN), in accordance with an embodiment of the present disclosure.

As shown, a first node 502, a second node 504, and a third node 506 form a triplet of neighboring spatial data points connected by edges 508 and 510. The nodes are arranged such that the edges 508 and 510 are approximately collinear within a predefined angular tolerance, for example within ±15 degrees. The triplet need not correspond to vertices of a single triangular face of the TIN and may span adjacent triangular regions sharing a common node. Each node is associated with spatial coordinates (x_i, y_i, z_i), and adjusted elevations may be represented as:

$${z}^{′} \_i = z\_base \_i + u\_i - d\_i$$

For the triplet (j, i, k), a slope value along each edge may be determined based on elevation difference and spatial distance. For example:

$$\begin{matrix}Slope\_ji = ( {z}^{′} \_j - {z}^{′} \_i ) / d\_ji \\ Slope\_ik = ( {z}^{′} \_i - {z}^{′} \_k ) / d\_ik\end{matrix}$$

where d_ji and d_ik represent spatial distances between neighboring nodes.

The curvature or slope-change constraint limits the difference between adjacent slopes such that:

$$\vert Slope\_ji - Slope\_ik \vert \leq Δ S\_max$$

where ΔS_max represents a maximum allowable rate of change of slope.

This constraint prevents abrupt changes in grade between neighboring edges and reduces the likelihood of creating sharp “V”-shaped indentations or unintended surface irregularities. The embodiment illustrated in FIG. 5A ensures smoother transitions across adjacent edges of the irregular mesh. In the illustrated embodiment of FIG. 5A, solid lines represent edges of the triangulated irregular network, and dashed lines are provided for illustrative purposes to indicate conceptual slope comparison relationships and need not represent additional mesh edges.

FIG. 5B illustrates an example representation of an interior face slope constraint applied within a triangular face 512 of the triangulated irregular network, in accordance with an embodiment of the present disclosure. The triangular face 512 is defined by three nodes 514 (A), 516 (B), and 518 (C). An interior reference point 520 (P), such as a centroid of the triangular face, may be defined based on the coordinates of the vertices.

In one embodiment, the interpolated elevation at the interior point 520 may be determined as:

$${z}^{′} \_P = ( {z}^{′} \_A + {z}^{′} \_B + {z}^{′} \_C ) / 3$$

The slope between the interior point 520 and each vertex of the triangular face may be constrained to satisfy a slope tolerance S_max. For example:

$$\vert {z}^{′} \_P - {z}^{′} \_A \vert \leq S\_max \times d\_PA$$

$$\vert {z}^{′} \_P - {z}^{′} \_B \vert \leq S\_max \times d\_PB$$

$$\vert {z}^{′} \_P - {z}^{′} \_C \vert \leq S\_max \times d\_PC$$

where d_PA, d_PB, and d_PC represent spatial distances between the interior point and respective vertices.

By enforcing slope constraints at interior locations within the triangular face 512, the system 200 ensures slope compliance not only at nodes and along edges but across the entire surface of each triangular region. This reduces the possibility of interior regions exceeding allowable slope tolerances even when vertex-based constraints are satisfied. In some embodiments, additional interior reference points or edge midpoints may be used to further refine slope control across triangular faces. The embodiments illustrated in FIGS. 5A and 5B are exemplary and not limiting. Additional higher-order constraints may be generated to regulate smoothness and slope compliance across the irregular mesh without departing from the scope of the present disclosure.

In certain embodiments, earthwork volume is determined using triangular regions defined by the irregular mesh representation, such as the triangulated irregular network (TIN). The TIN may include a plurality of triangular regions, each defined by three spatial data points representing terrain elevations. Each triangular region provides a planar approximation of a corresponding portion of the terrain surface. Adjusted elevation values at each node may be expressed as:

$${z}^{′} \_i = z \_base \_i + u\_i - d\_i$$

where u_i represents positive elevation adjustment (fill) and d_i represents negative elevation adjustment (cut).

Further, for a triangular region defined by vertices A, B, and C, an average elevation change may be computed as:

$$avg\_vertex \_elevation \_change = ( ( u\_A - d\_A ) + ( u\_B - d\_B ) + ( u\_C - d\_C ) ) / 3$$

The volume contribution of the triangular region may be determined as:

$$Volume\_triangle = A\_triangle \times avg\_vertex \_elevation \_change$$

where A_triangle represents the plan-view area of the triangular region.

The total earthwork volume may be determined by aggregating contributions from multiple triangular regions:

$$Volume\_total = Σ\_triangles ( A\_triangle \times avg\_vertex \_elevation \_change )$$

This triangle-based volume computation provides improved accuracy for irregular meshes compared to uniform cell-based approximations and enables consistent volume evaluation across variable edge lengths. In some embodiments, a baseline earthwork objective may be determined by reducing total elevation displacement represented as:

$$Σ\_i α\_i ( u\_i + d\_i )$$

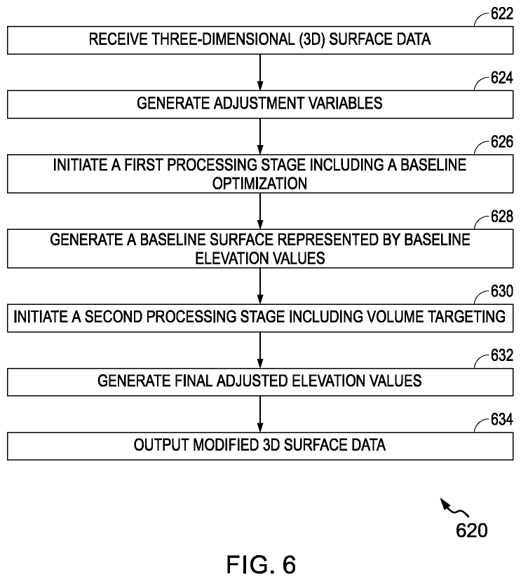

FIG. 6 illustrates a flow diagram representing a two-phase optimization workflow 620 for generating a graded terrain surface, in accordance with an embodiment of the present disclosure. The workflow 620 may be executed by the system described herein to determine adjusted elevation values for a plurality of spatial data points while satisfying slope-related and earthwork-related constraints.

At block 622, the system 200 receives the three-dimensional (3D) surface data including the plurality of spatial data points representing terrain elevations. The received data may include adjacency relationships defining an irregular mesh representation, such as the triangulated irregular network (TIN), and associated constraint parameters.

At block 624, the system 200 generates the elevation adjustment variables corresponding to the spatial data points of the received surface data. In one embodiment, each adjusted elevation value may be expressed as:

$${z}_{i}^{′} = {z}_{base , i} + {u}_{i} - {d}_{i}$$

where z_{base,i} represents a base elevation, uᵢ represents a positive elevation adjustment, and dᵢ represents a negative elevation adjustment.

At block 626, the system 200 performs a first processing stage including a baseline optimization. In this stage, adjusted elevation values are determined to satisfy slope-related constraints while minimizing an area-weighted objective function. In one embodiment, the objective function may be expressed as:

$$Σ\_i α\_i ( u\_i + d\_i )$$

or, in alternative embodiments,

$$Σ\_i α\_i ( {u\_i}^{2} + {d\_i}^{2} )$$

where αᵢ represents a nodal area weight associated with spatial data point i. The baseline optimization may be subject to slope constraints of the form:

$$\vert {z}_{j}^{′} - {z}_{i}^{′} \vert \leq {S}_{max} \cdot {d}_{ij}$$

and, where applicable, slope-change constraints of the form:

$$\vert \frac{{z}_{j}^{′} - {z}_{i}^{′}}{{d}_{ji}} - \frac{{z}_{i}^{′} - {z}_{k}^{′}}{{d}_{ik}} \vert \leq Δ {S}_{max}$$

At block 628, the system 200 generates a baseline surface represented by baseline elevation values z*ᵢ, corresponding to the solution obtained from the first processing stage.

At block 630, the system 200 performs a second processing stage comprising volume targeting. In this stage, a predefined earthwork volume condition is enforced to satisfy a net cut or fill requirement. The earthwork volume condition may constrain the area-weighted net elevation adjustment such that:

$$Σ\_i α\_i ( u\_i - d\_i ) = V\_target$$

where V_{target} represents a predetermined net earthwork volume requirement.

In certain embodiments, deviation control constraints are applied during the second processing stage to limit variation relative to the baseline surface. For neighboring spatial data points (j), deviation from baseline slope relationships may be limited as:

$$- Δ {S}_{band} \cdot {d}_{ij} \leq [ ( {z}_{j}^{′} - {z}_{i}^{′} ) - ( {z}_{j}^{*} - {z}_{i}^{*} ) ] \leq Δ {S}_{band} \cdot {d}_{ij}$$

where Δ_{Sband} represents a permissible deviation tolerance and dᵢⱼ represents spatial distance between neighboring spatial data points.

At block 632, the system 200 generates final adjusted elevation values satisfying both slope-related constraints and the net earthwork volume condition.

At block 634, the system 200 outputs modified 3D surface data corresponding to a graded terrain surface suitable for storage, visualization, earthwork estimation, or generation of grading control data for construction operations.

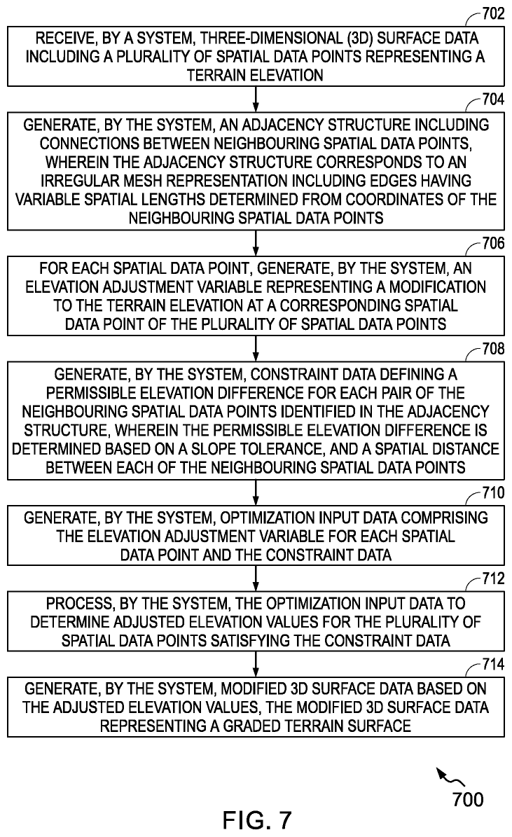

FIG. 7 illustrates a flowchart of a method 700 for grading designs of the TIN, in accordance with an embodiment of the present disclosure. The method 700 depicted in the flowchart is a computer-implemented method 700 that may be executed by, for example, the system 200. Operations of the flowchart, and combinations of operations in the flowchart, may be implemented by, for example, hardware, firmware, a processor, circuitry, and/or a different device associated with the execution of software that includes one or more computer program instructions. The method 700 starts at step 702.

At operation 702, the system 200 receives three-dimensional (3D) surface data including the plurality of spatial data points representing a terrain elevation.

At operation 704, the system 200 generates the adjacency structure including connections between neighboring spatial data points. The adjacency structure corresponds to the irregular mesh representation including edges having variable spatial lengths determined from coordinates of the neighboring spatial data points.

At operation 706, the system 200 generates the elevation adjustment variable representing the modification to the terrain elevation at the corresponding spatial data point of the plurality of spatial data points.

At operation 708, the system 200 generates constraint data defining the permissible elevation difference for each pair of the neighboring spatial data points identified in the adjacency structure. The permissible elevation difference is determined based on the slope tolerance, and the spatial distance between each of the neighboring spatial data points.

At operation 710, the system 200 generates optimization input data including the elevation adjustment variable for each spatial data point and the constraint data.

At operation 712, the system 200 processes the optimization input data to determine adjusted elevation values for the plurality of spatial data points satisfying the constraint data.

At operation 714, the system 200 generates modified 3D surface data based on the adjusted elevation values. The modified 3D surface data represent the graded terrain surface.

Various embodiments of the disclosure, as discussed above, may be practiced with steps and/or operations in a different order, and/or with hardware elements in configurations, which are different than those which, are disclosed. Therefore, although the disclosure has been described based on these exemplary embodiments, it is noted that certain modifications, variations, and alternative constructions may be apparent and well within the spirit and scope of the disclosure.

Although various exemplary embodiments of the disclosure are described herein in a language specific to structural features and/or methodological acts, the subject matter defined in the appended claims is not necessarily limited to the specific features or acts described above. Rather, the specific features and acts described above are disclosed as exemplary forms of implementing the claims.

What is claimed is:

1. A computer-implemented method for generating grading designs for a construction site, comprising:
receiving, by a system, three-dimensional (3D) surface data comprising a plurality of spatial data points representing a terrain elevation;
generating, by the system, an adjacency structure comprising connections between neighboring spatial data points, wherein the adjacency structure corresponds to an irregular mesh representation including edges having variable spatial lengths determined from coordinates of the neighboring spatial data points;
for each spatial data point, generating, by the system, an elevation adjustment variable representing a modification to the terrain elevation at a corresponding spatial data point of the plurality of spatial data points;
generating, by the system, constraint data defining a permissible elevation difference for each pair of the neighboring spatial data points identified in the adjacency structure, wherein the permissible elevation difference is determined based on a slope tolerance, and a spatial distance between each of the neighboring spatial data points;
generating, by the system, optimization input data comprising the elevation adjustment variable for each spatial data point and the constraint data;
processing, by the system, the optimization input data to determine adjusted elevation values for the plurality of spatial data points satisfying the constraint data; and
generating, by the system, modified 3D surface data based on the adjusted elevation values, the modified 3D surface data representing a graded terrain surface.

2. The method as claimed in claim 1, wherein determining adjacency relationships comprises generating a triangulated irregular network (TIN) from the plurality of spatial data points representing irregularly spaced terrain measurements.

3. The method as claimed in claim 1, wherein generating the adjacency structure relationships comprises generating a triangulated irregular network (TIN) from the plurality of spatial data points representing irregularly spaced terrain measurements, and wherein edges of the triangulated irregular network define the neighboring spatial data points.

4. The method as claimed in claim 1, further comprising constraining a difference between a set of total positive elevation adjustments and a set of total negative elevation adjustments to satisfy a predefined earthwork volume condition, and wherein the predefined earthwork volume condition specifies a non-zero net volume corresponding to a predetermined cut or fill requirement.

5. The method as claimed in claim 1, further comprising accessing requirement data defining a target grading region and eliminating one or more spatial data points among the plurality of data points outside the target grading region from processing during determination of the adjusted elevation values.

6. The method as claimed in claim 1, wherein the plurality of spatial data points comprises irregularly spaced survey data points.

7. The method as claimed in claim 1, wherein processing the optimization input data determines the adjusted elevation values that minimize a weighted total elevation displacement while satisfying the constraint data, wherein the weighted total elevation displacement comprises a summation of elevation adjustment magnitudes multiplied by respective nodal area weights associated with the spatial data points.

8. The method as claimed in claim 1, wherein the modified 3D surface data is configured to generate grading control data for an automated earthmoving equipment.

9. The method as claimed in claim 1, wherein the constraint data further comprises directional slope constraints determined based on directional components of each edge, such that different slope tolerances are applied depending on an orientation of the edge relative to predefined directional axes.

10. The method as claimed in claim 1, further comprising performing a first processing stage to determine baseline adjusted elevation values and a second processing stage to enforce a net-volume requirement while limiting deviation from slope relationships established during the first processing stage,
wherein the second processing stage maintains drainage direction established during the first processing stage by preventing reversal of slope direction between selected neighboring spatial data points.

11. The method as claimed in claim 1, wherein earthwork volume is determined based on areas of triangular regions defined by the adjacency structure and elevation changes at the vertices associated with each triangular region.

12. The method as claimed in claim 1, wherein additional slope constraints are generated for interpolated interior locations within triangular regions of the adjacency structure to ensure slope compliance across entire triangular faces.

13. The method as claimed in claim 1, wherein processing comprises using at least one of a linear adjustment procedure, a quadratic adjustment procedure, or a discrete-constrained adjustment procedure configured to preserve selected slope directions.

14. The method as claimed in claim 1, wherein the constraint data further comprises per-node elevation bounds associated with one or more spatial data points, the per-node elevation bounds comprising at least one of:
a minimum allowable elevation value,
a maximum allowable elevation value, and
a fixed elevation constraint preventing modification of a selected spatial data point, and
wherein processing the optimization input data enforces the per-node elevation bounds during determination of the adjusted elevation values.

15. The method as claimed in claim 1, further comprising defining a plurality of grading zones within the three-dimensional surface data, wherein each grading zone is associated with a distinct set of constraint parameters comprising at least one of slope tolerances, directional slope parameters, elevation limits, or earthwork conditions, and wherein the constraint data applied to a spatial data point is determined based on a grading zone in which the spatial data point is located.

16. A system, comprising:
a communication interface;
a memory storing executable instructions; and
a processor operatively coupled with the communication interface and the memory, the processor configured to execute the executable instructions to cause the system to at least:
receive three-dimensional (3D) surface data comprising a plurality of spatial data points representing a terrain elevation;
generate an adjacency structure comprising connections between neighboring spatial data points, wherein the adjacency structure corresponds to an irregular mesh representation including edges having variable spatial lengths determined from coordinates of the neighboring spatial data points;
for each spatial data point, generate an elevation adjustment variable representing a modification to the terrain elevation at a corresponding spatial data point of the plurality of spatial data points;
generate constraint data defining a permissible elevation difference for each pair of the neighboring spatial data points identified in the adjacency structure, wherein the permissible elevation difference is determined based on a slope tolerance, and a spatial distance between each of the neighboring spatial data points;
generate optimization input data comprising the elevation adjustment variable for each spatial data point and the constraint data;
process the optimization input data to determine adjusted elevation values for the plurality of spatial data points satisfying the constraint data; and
generate modified 3D surface data based on the adjusted elevation values, the modified 3D surface data representing a graded terrain surface.

17. The system as claimed in claim 16, wherein determining adjacency relationships comprises generating a triangulated irregular network (TIN) from the plurality of spatial data points representing irregularly spaced terrain measurements.

18. The system as claimed in claim 16, wherein generating the adjacency structure relationships comprises generating a triangulated irregular network (TIN) from the plurality of spatial data points representing irregularly spaced terrain measurements, and wherein edges of the triangulated irregular network define the neighboring spatial data points.

19. The system as claimed in claim 16, wherein the system is further caused to constrain a difference between a set of total positive elevation adjustments and a set of total negative elevation adjustments to satisfy a predefined earthwork volume condition, and wherein the predefined earthwork volume condition specifies a non-zero net volume corresponding to a predetermined cut or fill requirement.

20. The system as claimed in claim 16, wherein the system is further caused to access requirement data defining a target grading region and eliminating one or more spatial data points among the plurality of data points outside the target grading region from processing during determination of the adjusted elevation values.

21. The system as claimed in claim 16, wherein the plurality of spatial data points comprises irregularly spaced survey data points.

22. The system as claimed in claim 16, wherein processing the optimization input data determines the adjusted elevation values that minimize a weighted total elevation displacement while satisfying the constraint data, wherein the weighted total elevation displacement comprises a summation of elevation adjustment magnitudes multiplied by respective nodal area weights associated with the spatial data points.

23. The system as claimed in claim 16, wherein the modified 3D surface data is configured to generate grading control data for an automated earthmoving equipment.

24. The system as claimed in claim 16, wherein the constraint data further comprises directional slope constraints determined based on directional components of each edge, such that different slope tolerances are applied depending on an orientation of the edge relative to predefined directional axes.

25. The system as claimed in claim 16, wherein the system is further caused to perform a first processing stage to determine baseline adjusted elevation values and a second processing stage to enforce a net-volume requirement while limiting deviation from slope relationships established during the first processing stage,
wherein the second processing stage maintains drainage direction established during the first processing stage by preventing reversal of slope direction between selected neighboring spatial data points.

26. The system as claimed in claim 16, wherein earthwork volume is determined based on areas of triangular regions defined by the adjacency structure and elevation changes at the vertices associated with each triangular region.

27. The system as claimed in claim 16, wherein additional slope constraints are generated for interpolated interior locations within triangular regions of the adjacency structure to ensure slope compliance across entire triangular faces.

28. The system as claimed in claim 16, wherein processing comprises using at least one of a linear adjustment procedure, a quadratic adjustment procedure, or a discrete-constrained adjustment procedure configured to preserve selected slope directions.

29. The system as claimed in claim 16, wherein the constraint data further comprises per-node elevation bounds associated with one or more spatial data points, the per-node elevation bounds comprising at least one of:
a minimum allowable elevation value,
a maximum allowable elevation value, and
a fixed elevation constraint preventing modification of a selected spatial data point, and
wherein processing the optimization input data enforces the per-node elevation bounds during determination of the adjusted elevation values.

30. The system as claimed in claim 16, wherein the system is further caused to define a plurality of grading zones within the three-dimensional surface data, wherein each grading zone is associated with a distinct set of constraint parameters comprising at least one of slope tolerances, directional slope parameters, elevation limits, or earthwork conditions, and
wherein the constraint data applied to a spatial data point is determined based on a grading zone in which the spatial data point is located.
